(19) United States
(12) Patent Application Publication
(10) Pub. No.: US 2005/0085028 A1
(43) Pub. Date: Apr. 21, 2005

(54) Method and structure to suppress external latch-up

(75) Inventors: Kiran V. Chatty, Williston, VT (US); Peter E. Cottrell, Essex Junction, VT (US); Robert J. Gauthier JR., Hinesburg, VT (US); Mujahid Muhammad, Essex Junction, VT (US)

Correspondence Address: CONNOLLY BOVE LODGE & HUTZ LLP, SUITE 800, 1990 M STREET NW, WASHINGTON, DC, 20036-3425, US

(73) Assignee: International Business Machines Corporation, Armonk, NY (US)

(21) Appl. No.: 10/605,699

(22) Filed: Oct. 21, 2003

(51) Int. Cl. H01L 21/8238

(52) U.S. Cl. 438/200

(57) ABSTRACT

A method and structure for protection against latch-up is provided. Integrated circuits manufactured in accordance with the present disclosure feature well and substrate contacts of varying periodicity. Such a strategy enables maximizing the design of an integrated circuit as to the suppression of latch-up while concurrently optimizing available area on the chip allocable to circuit design. This method and structure is particularly beneficial to protect against cable discharge events and other discharge occurrences prone to injecting large current densities into an integrated circuit.

### BACKGROUND OF INVENTION

1. Field of the Invention

The present invention relates generally to latch-up protection for integrated circuits, and more particularly to the strategic placement of n-well, p-well or substrate contacts for external latch-up robustness.

2. Background of the Invention

Advances in modern integrated circuit (IC) technology have enabled MOS devices to be made with ever thinner gate oxides using submicron complementary metal oxide semiconductor (CMOS) technology. Use of thinner gate oxides, however, results in devices that are increasingly susceptible to failure arising from electrical overstress/electrostatic discharge (EOS/ESD) events. Such failures can result in the immediate failure of the device, circuit or system.

To reduce the destructiveness of an ESD event, IC designers incorporate protective circuits within their IC layouts to dissipate the energy of a discharge. Such ESD protection circuitry is typically located at or near the input/output (I/O) pad of the IC and must withstand industry standard testing for an IC device to be qualified for commercial applications. Several models exist to simulate ESD events in order to test the effectiveness of protection circuitry. The models are generally classified into one of three forms: the human body model (HBM), the machine model (MM), and the charged device model (CDM). The HBM simulates the action of a human body discharging accumulated static charge through a device to ground. The model employs a series RC network consisting of a 100-pF capacitor and a 1500-Ohm resistor. The MM simulates a machine discharging accumulated charge through a device to ground. The model utilizes a series RC network of a 200-pF capacitor and nominal series resistance of less than one ohm. The CDM simulates the charging/discharging that is found to occur in production equipment and processes. CDM ESD events occur as a result of metal-to-metal contact that can arise during manufacturing, such as a device sliding down a tube and hitting a metal surface. CDM testing consists of charging a package to a specified voltage, then discharging this voltage through relevant package leads.

Another destructive phenomenon that can cause premature failure of IC devices is Cable Discharge Event (CDE). CDE can occur when a charged cable connects to a port or device of lower electrical potential. When a charged cable contacts the port or device of lower potential, a transfer of energy occurs through discharge of the cable that can destroy the port connector and circuitry of the device.

Cables can accumulate charge through triboelectric effects, as when a cable is dragged across carpet or pulled through conduit. Such frictionally induced charge typically occurs in new installations when unterminated cables are handled. Cables can also accumulate charge through induction effects, such as when a cable is exposed to electromagnetic fields, as can occur when cables are brought in proximity to electromagnetic devices such as transformers and light ballasts. And because modern cables feature very low leakage, the charge accumulated by the cable can remain stored for a long period of time. The charged cable is in essence a charged capacitor poised for discharge with the cable's conductor(s) serving as one plate of the capacitor, earth ground as the other plate, and the cable's insulation acting as the dielectric.

On the occurrence of ESD or CDE, carriers injected into an IC can trigger latch-up. Latch-up is the appearance of a low impedance path between power supply rails that results from the triggering of parasitic devices within the CMOS structure. It is an inherent byproduct of modern CMOS design and arises due to the close proximity of n-channel and p-channel devices within the CMOS wafer. Latch-up is a problem inherent to bulk starting-wafer CMOS.

There are two main types of latch-up: internal latch-up and external latch-up. Internal latch-up arises when parasitic devices within the CMOS structure are triggered from sources such as internal circuits creating supply bounce, transmission line reflections or on-chip generation of carriers. External latch-up arises when the parasitic devices are triggered by off-chip signals. These off-chip signals can create large carrier injection to trigger latch-up in the I/O itself or within neighboring circuits in proximity to the I/O, as well as stimulate large voltage bounce, which then can trigger internal latch-up.

Latch-up testing of ICs is performed in accordance with EIA/JEDEC Standard EIA/JESD78, which requires, in part, injection of current at the I/O of the Device Under Test (DUT) in both positive and negative modes. Because the ESD device is the first circuit connected to the I/O pad, it is the first device to turn ON and is the lowest impedance device connected to the I/O pad when latch-up testing is conducted. During testing, when positive current is injected, any p-type region connected to the pad will forward-bias. When negative current is injected, the n-type region will forward-bias.

On a p-substrate, during positive mode testing, any p-type device connected to the I/O pad will usually inject holes into the substrate. These majority carriers can be controlled by moderating the resistance of the local substrate contacts. Thus, the positive mode injection test can be handled locally around the ESD device by use of substrate rings (guard rings) to control substrate resistance. In negative mode testing, however, minority carriers (electrons) are injected into the p-substrate. Many of the injected minority carriers are collected by n-well guard rings, but not all can be collected without adding exceptional process complexity and costs. Thus, some electrons escape and the higher the doping of the p-type substrate, the shorter the distance the electrons will diffuse. On a p-substrate, however, the escaped electrons can diffuse a distance of up to 600 microns and therefore serve as a latch-up trigger in other circuitry on the substrate.

Diffusion of electrons through a p-substrate is illustrated in FIG. 1. Although FIG. 1 illustrates the flow of electrons in a p-substrate, positive carriers may also be injected into the substrate, which itself may be formed of n-type material. Carriers enter the IC through a point of entry such as an I/O pad due to an injection event, such as ESD or CDE. Injected carriers traverse though the I/O cell 101 and into substrate 100. Some carriers are collected by guard ring 102, but not all carriers are gathered and thus some continue to flow through the substrate. These escaped carriers are available to enter other areas of the IC, such as well regions, and can operate to alter the local potential. FIG. 1 shows electrons entering n-well 103 that operate to lower the local n-well potential. As will be described below, lowering of the local n-well potential can trigger a condition of latch-up.

A typical dual-well latch-up structure can be seen by referring to FIGS. 2A and 2B. FIG. 2A shows the formation of a latch-up structure that comprises parasitic bipolar junction transistors Q1 and Q2 with associated horizontal and vertical components of well resistance; FIG. 2B shows the equivalent circuit of the structure. Charge carriers are introduced to the substrate by the occurrence of a carrier injecting event, such as ESD or CDE, thus forming current I_{Inj}. Current I_{Inj} flows through the IC as described above in reference to FIG. 1. If a small stray current I_{NW} flows through an n-well, a voltage drop will form through the n-well by virtue of n-well resistance R_{NW}. N-well resistance R_{NW} is comprised of horizontal and vertical components, which are designated in FIG. 2A as R_{NW-h} and R_{NW-v} respectively. P-well resistance R_{PW} is similarly comprised of horizontal and vertical components, designated in FIG. 2A as R_{PW-h} and R_{PW-v}, respectively. In general, the horizontal resistance of a doped region such as a well will depend on physical dimensions, such as length, width and depth, and sheet resistance, which is a process dependent technology parameter. The vertical resistance of the well is also a function of the physical dimensions of the well, the sheet resistance, and the size and resistance of the well contact.

An inherent byproduct of diffusing one type of material (for example, p-type) within material of the opposite type (n-type) is the formation of p-n junction diodes at the interface of the materials. Thus, an n-well containing p+ regions will inherently contain p-n junction diodes for each p+ region/n-well boundary. When current flowing through an n-well over resistance R_{NW} is of such a magnitude that the potential drop within the n-well reaches the turn-on voltage of the p+/n-well junction diode, the p+/n-well junction diode will forward-bias, thus activating (turning ON) the parasitic pnp bipolar junction transistor (BJT) Q1. When Q1 turns ON, carriers flow into the p-well across the n-well/p-well junction, which is forward-biased due to the reduced n-well potential. These carriers form collector current I_{CQ1} of Q1. As I_{CQ1} flows through the p-well over p-well resistance R_{PW}, a rise in the local potential within the p-well forms. When the potential rise within the p-well reaches the turn-on voltage of the p-well/n+ junction diode, the p-well/n+ junction will forward-bias, thus activating the parasitic npn BJT Q2. An active Q2, in turn, will feed Q1 by drawing current I_{BQ1} from the base of Q1, which causes Q1 to turn ON “harder,” which in turn causes Q2 to turn ON harder, and so on. This positive feedback condition ensures that both Q1 and Q2 remain “latched” in the forward/active mode. Thus latched, the circuit is no longer dependent upon the triggering source for energy and a continual low impedance/short-circuit path exists between Vdd and ground/Vss.

A typical single-well latch-up structure can be seen by referring to FIGS. 3A and 3B. FIG. 3A shows the formation of a latch-up structure that comprises parasitic bipolar junction transistors Q1 and Q2 with associated well resistance R_{NW} and substrate resistance R_{S}; FIG. 3B shows the equivalent circuit of the structure. Although the single-well latch-up structure illustrated and described here is directed to an n-well within a p-type substrate, it should be understood that latch-up can also occur in a structure possessing a p-well within an n-type substrate with polarities opposite to that described here.

In reference to FIG. 3A, when charge carriers are injected into the substrate by the occurrence of a carrier injecting event, such as ESD or CDE, and a small stray current (I_{S}) flows through the p-substrate over the substrate internal resistance R_{S}, a voltage rise will form across the substrate. If the potential difference between the p-substrate and n+ region within the substrate reach the diode built-in voltage level, i.e. the diode's turn-on voltage, the junction will forward-bias, forming thereby the emitter-base junction of Q2, which is thus activated (turned ON). As Q2 turns ON, current is drawn from the n-well, which in turn causes a voltage drop to form across n-well resistance R_{NW}. If the potential within the n-well reaches a diode built-in voltage level (below Vdd), the emitter-base junction of Q1 will forward-bias and turn Q1 ON. As Q1 turns ON, Is increases, which causes Q2 to turn ON “harder,” which in turn causes Q1 to turn ON harder, and so on. This positive feedback condition ensures that both Q1 and Q2 remain ON in the forward/active mode; and the current flowing through each transistor ensures that the other remains ON. Thus latched, the circuit is no longer dependent on the triggering source and a continual low-impedance/short-circuit path exists between Vdd and ground/Vss.

As discussed previously, the semiconductor industry employs a standard JEDEC78 latch-up test to evaluate the robustness of a particular IC design against DC current pulses. Carrier injection from CDE is, however, far stronger; several amperes of transient current is injected making it more severe than that tested under a JEDEC78 latch-up test. As of date, no such standard test is available to certify against CDE. With CDE, however, designers will typically employ Transient Voltage Suppression (TVS) diodes to divert CDE energy away from IC circuitry. TVS diodes are similar to zener diodes in that they are designed for low capacitance and rapid breakdown above the clamping voltage. Standardized field installation procedures can also be employed that require proper discharge of cables to ground before connection/termination.

To design ICs that are resistant to latch-up, designers can adjust the value of the contact periodicity to meet the latch-up standard. Conventional industry practice is to provide contacts having a fixed periodicity (L) throughout the chip. FIG. 4 illustrates an IC layout having contacts of fixed periodicity. Note that the contact periodicity L1 is the same throughout the chip, thus the distance between adjacent contacts is the same. Though use of a fixed contact periodicity may be adequate to design against standardized JEDEC78 test, the practice is costly in terms of process complexity and loss of chip area available to designers for circuit layout. Sacrifice of chip area to prophylactic contacts is particularly problematic for designers attempting to provide circuits that are resistant to CDE induced latch-up because the higher carrier injection of CDE necessitates use of smaller contact periodicity, which results in a significant loss of useful chip area. Thus, designers of CDE latch-up robust circuits are forced to surrender valuable chip area to contacts, or compromise by using some intermediate level of protection that necessitates reliance on the discipline of field personnel to properly discharge cables prior to installation. Given human nature and the vulnerability of human processes, such reliance on personnel procedural discipline is not without risk.

Accordingly, what is needed are ICs that provide CDE latch-up robustness while at the same time minimizing the loss of chip area allocated to contacts, and a method of producing the same. What is further needed is a design tool to help IC designers to create such latch-up robust ICs.

### SUMMARY OF INVENTION

Aspects of the present invention feature a method and structure for suppression of latch-up within integrated circuits (ICs). ICs designed in accordance with the present invention contain substrate and well contacts that vary in periodicity, thus distance between adjacent contacts will vary. This disclosure recognizes that injected current density will be lower in areas of the IC that are remote from locations undergoing carrier injection, e.g., from electrostatic discharge or cable discharge events, than in areas nearer to the injection location. The present invention enhances the use of chip protection to reflect the variant spread of current density throughout the chip arising from an injection event.

The propensity of a given circuit structure within a chip to undergo latch-up is a function of the internal resistance of that structure and its distance from a point of current injection. Circuit structures that are susceptible to latch-up are referred to as latch-up structures. The further a given latch-up structure is from the point of current injection, the fewer the carriers there will be that are available to latch-up the structure, the higher the internal resistance of the structure may afford to be. The present invention provides for management of the internal resistance of circuit structures by utilizing the tolerance for increased resistance within a given structure vis-à-vis its distance from a current injection site, yet providing adequate latch-up protection. This control is effectuated through the strategic use of substrate and well contacts. The periodicity of contacts is varied such that the quantity of contacts within a given structure are minimized, yet the structure is still capable of suppressing latch-up. Since fewer contacts are needed for a given protection scheme, designers are then able to utilize the increase in available chip area for circuit design. Designers can provide circuits that are capable of withstanding severe injection of current, as can occur with cable discharge, yet maintain suppression of latch-up. Thus, this disclosure is suitable for applications involving, for example, servers and control stations where hot plugging of cables occurs.

In one embodiment of the present invention, the invention comprises a semiconductor structure comprising: a substrate; a plurality of circuit structures formed upon the substrate, wherein at least one of said circuit structures has a susceptibility to a latch-up condition; an injection site associated with the semiconductor structure; and a plurality of contact regions inter-spaced a varying distance between the circuit structures.

In another embodiment of the present invention, the invention comprises a method of forming a semiconductor structure having improved latch-up robustness, the method comprising the steps of providing a substrate including an injection site and a plurality of circuit structures, wherein at least one of the circuit structures has a susceptibility to a latch-up condition; and forming a plurality of contact regions inter-spaced a varying distance between the circuit structures.

In another embodiment of the present invention, the invention comprises program storage device readable by a machine, tangibly embodying a program of instructions executable by a machine to perform a method of designing an integrated circuit, the method comprising the steps of: receiving an integrated circuit design, the design providing for a plurality of circuit structures within a substrate; identifying at least one injection site associated with said integrated circuit design; identifying circuit structures as susceptible to a latch-up condition; determining a plurality of contacts for the circuit structures susceptible to a latch-up condition, the quantity being that necessary to suppress a latch-up condition within the identified circuit structures; and determining a location for the contacts so that the contacts are located to have a distance that varies with the proximity of the contacts to the at least one injection site.

In another embodiment of the present invention, the invention comprises a computer-readable medium having a plurality of computer executable instructions for causing a computer to design an integrated circuit, the computer executable instructions comprising the steps of: receiving an integrated circuit design, the design providing for a plurality of circuit structures within a substrate; identifying at least one injection site associated with the integrated circuit design; identifying circuit structures as susceptible to a latch-up condition; determining a quantity of contacts for the circuit structures susceptible to a latch-up condition, the quantity being that necessary to suppress a latch-up condition within the identified circuit structures; and determining a varying distance for the contacts, wherein the distance varies with the proximity of the contacts to the at least one injection site.

### BRIEF DESCRIPTION OF DRAWINGS

FIG. 1 illustrates cross-section of an integrated circuit showing typical electron flow within a substrate following a current injection event.

FIG. 2A illustrates a cross-section of a dual-well CMOS structure with parasitic bipolar junction transistors Q1 and Q2.

FIG. 2B illustrates a schematic diagram of the equivalent circuit formed by the parasitic bipolar junction transistors depicted in FIG. 3A.

FIG. 3A illustrates a cross-section of a single-well CMOS structure with parasitic bipolar junction transistors Q1 and Q2.

FIG. 3B illustrates a schematic diagram of the equivalent circuit formed by the parasitic bipolar junction transistors depicted in FIG. 3A.

FIG. 4 illustrates a plan view of a conventional integrated circuit having contacts of fixed periodicity.

FIG. 5 illustrates a flow diagram presenting the steps performed in an embodiment to arrive at an IC having contacts of varying periodicity.

FIG. 6A illustrates a plan view of a portion of an integrated circuit having contacts of varying periodicity in accordance with an embodiment of the present invention.

FIG. 6B illustrates a cross-section of a portion of an integrated circuit having contacts of varying periodicity in accordance with an embodiment of the present invention.

FIG. 7A illustrates a plan view of a portion of an integrated circuit having contacts of varying periodicity in accordance with an embodiment of the present invention.

FIG. 7B illustrates a plan view of a portion of an integrated circuit having contacts of varying periodicity in accordance with an embodiment of the present invention.

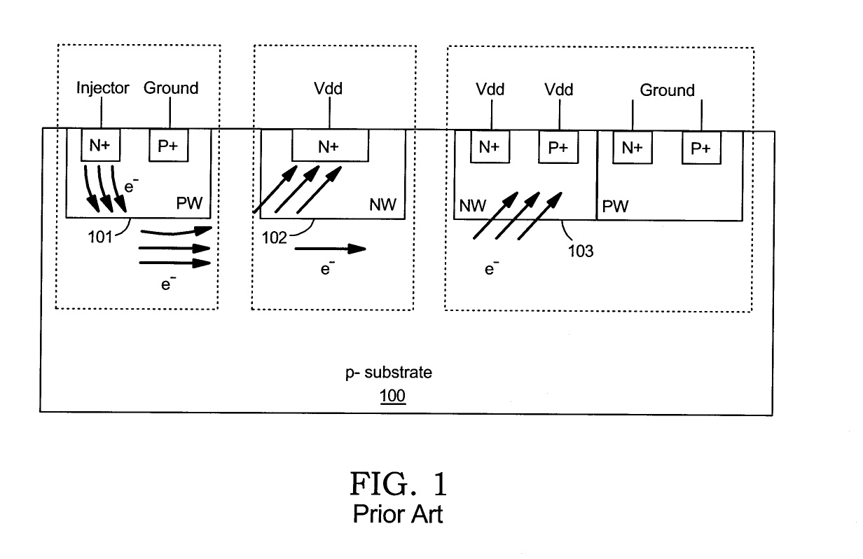

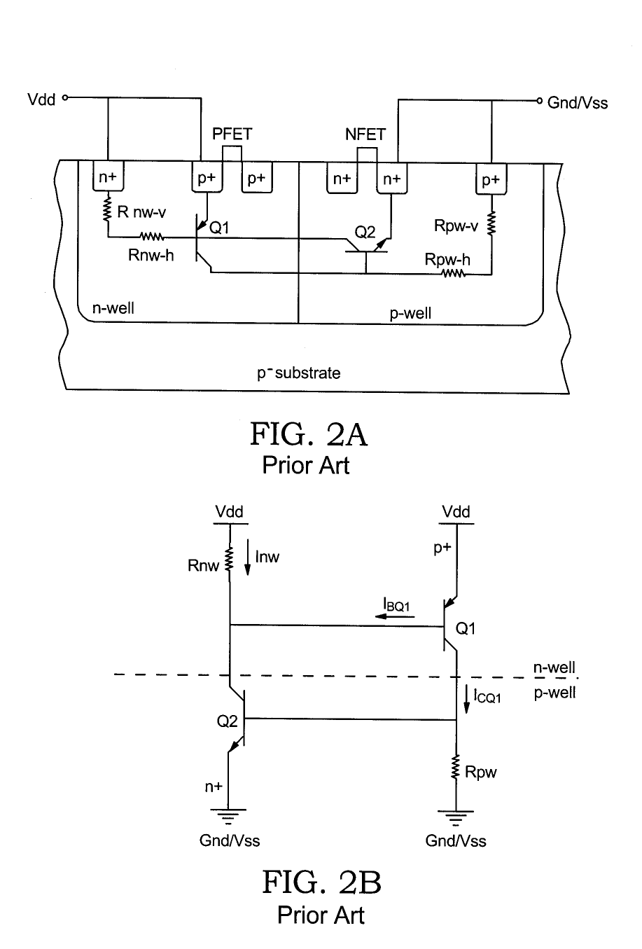

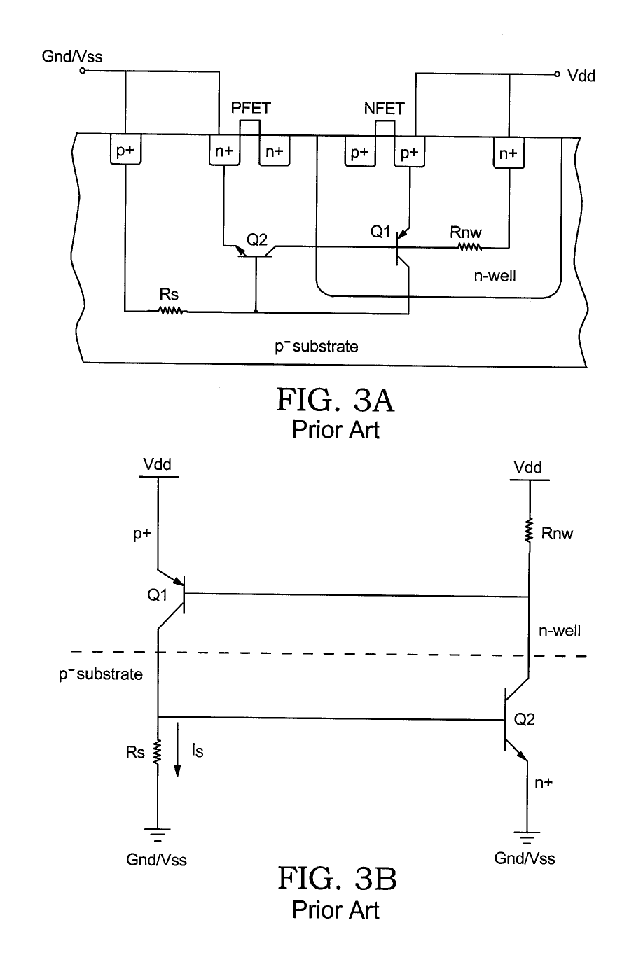

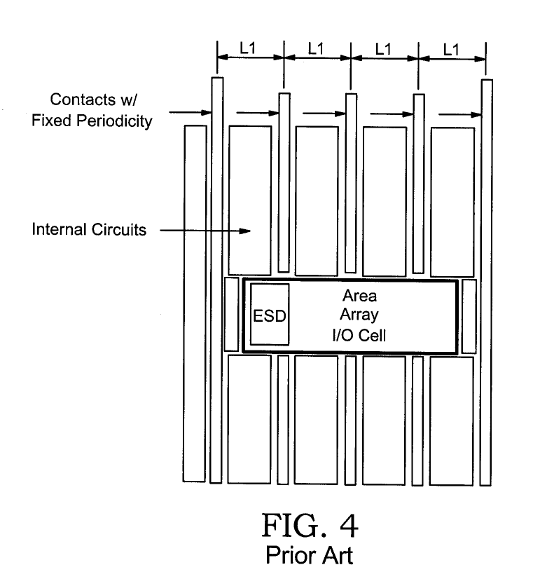

### DETAILED DESCRIPTION

The present invention relates to a method and structure for suppression of latch-up within integrated circuits. Injection of carriers into an IC can arise at any point of conduction on the IC and can originate from a variety of sources. Regardless of injection source and location, the density of injected carriers will be greatest within the region of the IC near the location of injection, i.e. the injection site. It is in the region near the injection site where protection against latch-up should be the most robust. As distance is traversed away from the location of current injection, however, there will be fewer carriers available to cause a latch-up condition. Thus, the latch-up protection strategy remote from the injection source need not be as robust as it need be nearer the injection source, yet maintaining latch-up robustness for a given injection of current.

In terms of electrical variables, a latch-up condition can occur when the injected current, for example, current from a JEDEC78 test or an ESD or CDE event, that reaches the base of a first parasitic transistor (I_{Inj-Base}) is greater than or equal to the sum of the base current of that transistor (I_{BQ1}) and the lateral current through the n-well resistance (I_{NW}); i.e., when I_{Inj-Base}≧(I_{BQ1+}I_{NW}). The magnitude of the current required to turn ON the first parasitic transistor is: I_{NW}=V_{Diode Turn-on}/R_{NW}; and the base current of the first parasitic transistor (I_{BQ1}) necessary to forward bias and turn ON a second parasitic transistor is: V_{Diode Turn-on}/(R_{NW}*Beta), where Beta is a transistor parameter representing the current gain of the first parasitic transistor, and R_{NW} is the n-well resistance.

From this model it is seen that a given IC can be made more latch-up robust, i.e., the potential for latch-up can be minimized, by maximizing the values of current I_{BQ1} and I_{NW} necessary to trigger latch-up. This forces latch-up to trigger only at higher values of injected current. And given the inverse relationship of current and resistance under Ohm's Law, maximizing current requires minimizing the internal resistance of a circuit structure, i.e., R_{NW} and R_{PW}, where R_{PW} is the p-well resistance. Thus, a latch-up robust design entails making R_{NW} and R_{PW} as small as possible.

IC designers incorporate contacts (i.e., diffusion regions within a semiconductor structure or device; for example, p+ regions within a p-well or p-type substrate, or n+ regions within an n-well or n-type substrate) into the circuit layout in order to maintain a low well resistance, bias the well appropriately for circuit functionality, and to collect stray current that is injected into the wells or substrate during a JEDEC78 test, an ESD or CDE event. Typically, the p-well or substrate contacts (p+ regions) are biased to ground potential, or Vss, and the n-well contacts (n+ regions) are biased at Vdd potential (supply voltage of the IC). The contacts are typically placed in the circuit layout via contact books, which comprise n-well, p-well or substrate contacts with appropriate connections. One example of a contact book is the NWSX contact book. The distance between adjacent groups of contact books placed in a circuit layout is reflected in a value referred to herein as “periodicity.” The smaller the periodicity, the lower the internal resistance of the semiconductor structure, the better the protection against turning on parasitic junctions within the semiconductor structure that result in latch-up.

Because the quantity and spacing of contacts are provided, in part, to effectuate a given latch-up protection strategy, fewer contacts need be employed in areas of the IC remote from the injection site. Accordingly, various aspects of the invention propose locating contacts to have varying periodicity to satisfy latch-up robustness at structures that are at various distances from the location of current injection. Thus, contact periodicity may be greater, i.e. fewer contacts need be used, in areas of the IC remote from the injection source than nearer the injection source, yet sustaining an appropriate level of latch-up robustness. The quantity of contacts can therefore be minimized to a quantity that is just necessary to suppress latch-up. By locating contacts to have a varying periodicity and minimizing the overall quantity of contacts within a latch-up robust design, a significant savings in process complexity and expense can be achieved, as well as freeing valuable chip area that may then be used for design which otherwise would be reserved for contact placement.

For the purposes of this disclosure, elements that inject current into the IC are referred to as “injectors.” The location where an injector injects current is referred to as an “injection site.” Injectors may be cables that discharge carriers into the IC upon contact, ESD diodes that inject carriers into the substrate via their diffusion regions, I/O pads that receive discharge from EOS/ESD events, etc. Thus, an injector represents any possible source, or combination of sources, of current to the IC, either internal current injector (on-chip injector) or external current injector (off-chip injector). Additionally, the implementation of a process conducted in accordance with an aspect of the present invention is described herein as being carried out on a computer. A computer, however, is not essential to perform the steps of the invention or to manufacture integrated circuits in accordance thereof. The novel steps may be performed manually without machine aid, or through a combination that employs a logical system with human input. If a computer is used, however, software employed to carry out the process may be implemented in hardware or firmware, or stored on one or more computer-readable media. The computer readable medium may comprise memory storage that is volatile or nonvolatile, and may comprise one or more components.

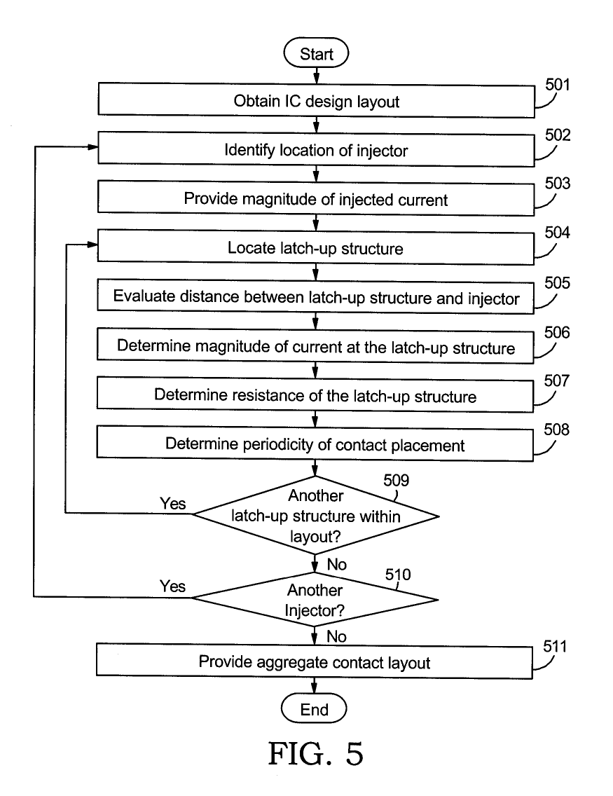

FIG. 5 illustrates a flow diagram of an embodiment of the invention presenting steps performed in designing and manufacturing an IC having contacts of varying periodicity. To begin, an IC design layout is obtained 501. The user of this inventive system may have created the design themselves or have received the design from another entity. The process comprising the steps performed in accordance with FIG. 5 may be implemented in software and as such operable on any viable computing platform. Such a software implemented process may comprise a design tool, which may be a subpart of a larger computer aided design/computer aided manufacturing (CAD/CAM) program, or program unto itself. Further, a software implemented design may be object oriented wherein elements of the design are represented by software components, which in turn can be data structures. Such data structures could be objects in an object oriented environment. Further, such data structures could be embedded within the software implementation of the design. As used herein, data structure is to be broadly construed and includes such software constructs as data bases. Constituent elements of the design include, for example, substrate, wells, and circuit structures of an integrated circuit.

Step 502 may be employed to identify the location of injectors within the design. It is contemplated that a given design will have one or more injectors and a user may select one or more of the available injectors to design against. The location of injectors may be provided by a user or they may be within a data structure or database configured to store the location of injectors. Alternatively, the injectors may form individualized data structures each associated with the design layout; a component of each individualized data structure being location.

Another step 503 is to provide the magnitude of current injection for which the system is to be designed to protect against. The magnitude of current may be provided as part of a standardized test, or estimated based upon possible conditions of installation, such as cable discharge. Magnitude of current may be revisited time and again by a user to repeatedly operate the system in order to arrive at an optimized design. This reiteration process may be automated.

Circuit structures comprise the internal circuitry of the IC and include, for example, field effect transistors (FETs), capacitors, resistors, and other such circuit elements. Circuit structures within a design that are susceptible to latch-up are referred to herein as “latch-up structures.” It is contemplated that a given design will have one or more latch-up structures and a user may select one or more latch-up structures to utilize in determining periodicity of contacts. The circuit structures have associated physical properties that impact on a given structure's propensity to latch-up. Such physical properties include, among others: quantity, placement, doping, dimensions, and internal resistance of wells; quantity, placement, and internal resistance of contacts; and internal resistance of the structure itself, which, in part, comprises contributions from the well and contact resistance. Step 504 locates circuit structures within the design that are susceptible to latch-up. Location information may be supplied by the user or provided by another entity, such as a third-party or via a data structure. The location of each latch-up structure may be obtained seriatim, i.e. one-by-one as part of a loop routine configured to operate upon data via a data structure on each iteration, which is suggested by the logic illustrated in the flow diagram. Alternatively, the location of each latch-up structure may be within a data structure or database configured to store the location of the latch-up structures. Alternatively, the latch-up structures may form individualized data structures each associated with the design layout; a component of each individualized data structure being location. Combinations of any of the above location methodologies may also be employed.

Evaluation of the distance between each latch-up structure and each injector is accomplished in step 505. As with step 504, this determination may be made seriatim, i.e. one-by-one (one latch-up structure, one injector) as part of a loop routine configured to operate upon data via a data structure on each iteration, which is suggested by the logic illustrated in the flow diagram. Additionally, the flow diagram is nested to provide a multidimensional collection of data points. Thus, if there are n injectors and m latch-up structures, then there will be n×m collected data sets. Alternatively, the distance between each latch-up structure and each injector may be within a data structure or database configured to store this data. Alternatively, the distance between each latch-up structure and each injector may form individualized data structures each associated with the design layout; a component of each individualized data structure being distance. Combinations of any of the above distance determination methodologies may also be employed.

Another step 506 is to determine the magnitude of current at each latch-up structure. The current at each latch-up structure is, in part, a function of the magnitude of the current provided by the injector, and the distance between the structure and the injector. Thus, determining the magnitude of current at each latch-up structure may be made seriatim, i.e. one-by-one as part of a loop routine configured to operate upon data via a data structure on each iteration, which is suggested by the logic illustrated in the flow diagram. Additionally, when multiple injectors are to be provided for, injected current from each injector will contribute carriers to the overall magnitude of current at each latch-up structure, i.e. the contribution of current from each injector will superimpose upon the others. Alternatively, the magnitude of current at each latch-up structure may be held within a data structure or database configured to store this data. Alternatively, the magnitude of current at each latch-up structure may form individualized data structures each associated with the design layout; a component of each individualized data structure being current magnitude. Combinations of any of the above current magnitude determining methodologies may also be employed.

Determining the magnitude of current that reaches a latch-up structure can also be made via electrical measurements on a test chip having certain structures, or calculated using commercial semiconductor simulators, such as, for example, the ISE-DESSIS. Alternatively, the current magnitude can be calculated by solving semiconductor transport equations.

To determine the resistance of the latch-up structure itself, step 507 may be employed. Information on latch-up structure resistance may be supplied by the user or provided by reference to another entity or source, such as a design guide. As with step 504, determination of resistance may be made seriatim, i.e. one-by-one as part of a loop routine configured to operate upon data via a data structure on each iteration, which is suggested by the logic illustrated in the flow diagram. Alternatively, the determination of resistance may be held within a data structure or database configured to store resistance values. Alternatively, the resistance values may form individualized data structures each associated with the design layout; a component of each individualized data structure being resistance. Combinations of any of the above resistance determining methodologies may also be employed.

Determining the periodicity (L) of contact placement necessary to make a particular structure robust to latch-up is accomplished in step 508. Given the magnitude of current available at each latch-up structure determined in step 506, and the resistance of the latch-up structure itself as obtained in step 507, the quantity of contacts and their periodicity of placement is determined for a particular latch-up structure to be latch-up robust. Each latch-up structure will have its own associated periodicity (L) in order to achieve the ability to suppress latch-up.

Steps 507 and 508 may be performed in conjunction with one another to determine both latch-up structure resistance and contact periodicity within the same analytical structure. Resistance of a latch-up structure may be expressed in terms of contact periodicity and, likewise, the contact periodicity may be expressed in terms latch-up structure resistance. Thus, a closed-form evaluation of the analytical structure modeling the design is employed. For a given magnitude of injected current, a set of periodicity values can be determined as a function of distance to the injection site such that a certain periodicity is determined for a given distance away from the injection site in order to avoid latch-up.

Step 509 tests for the presence of additional latch-up structures. If there are additional latch-up structures, the process of determining periodicity can be performed for those structures as well. This step will be unnecessary if the location of all latch-up structures is provided for within a data structure since logical manipulation can be made upon the data structure.

Step 510 tests for the presence of additional injectors. If there are additional injectors, the effect of their contribution can be accounted for as well. This step will be unnecessary if each injector is provided for within a data structure since logical manipulation can be made upon the data structure.

When the contact periodicity (L) necessary to make each latch-up structure robust to latch-up has been determined, an aggregate contact layout will be made for the design 511. The aggregate contact layout will incorporate the contribution of periodicity (L) of each latch-up structure. Because latch-up structures of differing periodicity may be in close proximity to one another, a designer may make elect to choose one periodicity over the other. For example, a designer may select the more conservative or worst case periodicity as between neighboring latch-up structures. Alternatively, a designer may elect to choose an intermediate contact periodicity based on experience.

At the conclusion of step 511, the design of an IC having contacts of varying periodicity should be completed.

It is contemplated that the steps taken in accordance with this disclosure will be performed in a sequence resembling that described, but this is not essential to arriving at an IC having contacts of varying periodicity because some steps may be performed before others, or some steps may be performed by different entities and thus omitted by the user.

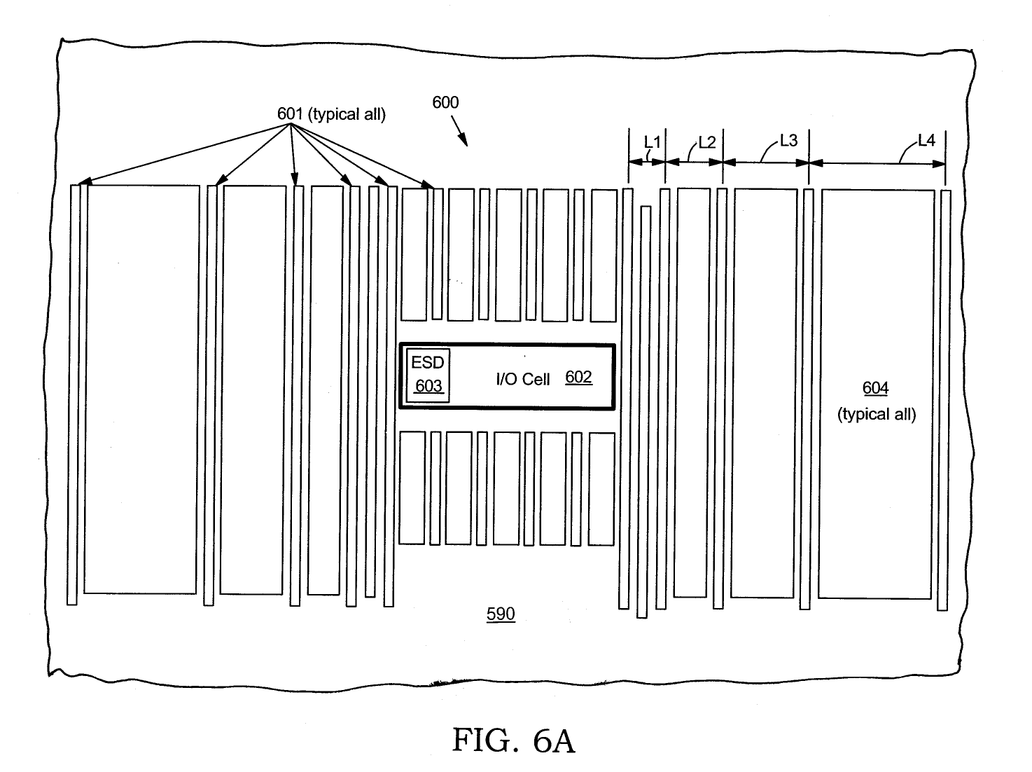

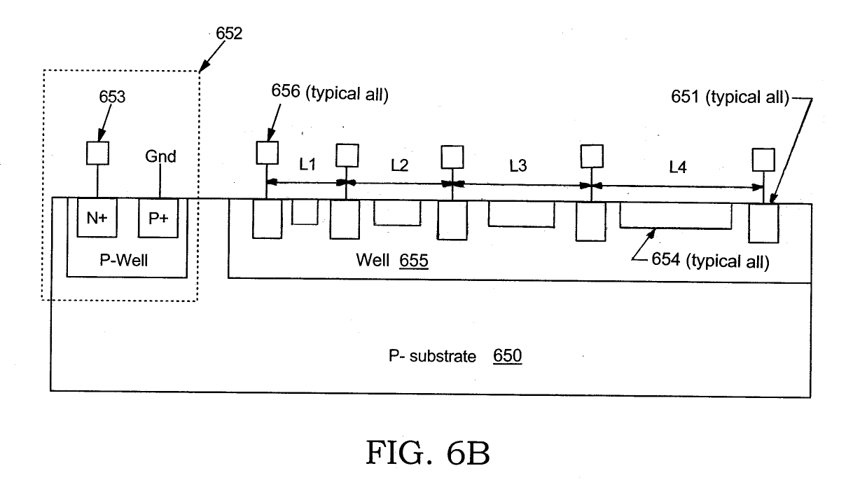

FIG. 6A illustrates a plan view of a portion of an integrated circuit 600 formed on substrate 590. IC 600 includes groups (or regions) of contacts 601 of varying periodicity in accordance with one embodiment of the invention. FIG. 6A illustrates a portion of an integrated circuit 600 with contacts 601 arranged vertically. In the region of the IC near the injection site, shown here as I/O cell 602 and ESD diode 603, the periodicity of contacts 601 is smaller than the periodicity utilized as distance is traversed away from the injection site. IC areas 604 include structures that may be susceptible to latch-up; for example, internal circuits that include n-wells and p-wells. Current injected into the injection site will have the highest density at or near the injection site. Thus, in order to avoid causing latch-up within circuit structures 604, the quantity of contacts needed for circuit structures 604 near the injection site is greater than for circuit structures 604 remote from the injection site. Thus, periodicity L4 is greater than periodicity L3, which is greater than periodicity L2, which is greater than periodicity L1. Periodicity L1, being smallest, calls for a greater number of contacts than periodicities L2-L4. In one embodiment, each of contacts 601 represents multiple NWSX contact books where L1-L4 are defined as the distance between adjacent contacts 601.

It should be noted that although periodicity L4 has been described as being greater than periodicity L3, which has been described as being greater than periodicity L2, which has been described as being greater than periodicity L1, any combination of contact periodicity is contemplated as being varying. For instance, periodicity L1 could equal periodicity L3, with periodicity L2 as being less than periodicity L1 or L3, and periodicity L4 as being greater than periodicity L1 or L3. Such a configuration could arise when a circuit structure remote from the injector is more susceptible to latch-up than a circuit structure closer to the injector. Thus, varying periodicity, or distance, is any periodicity other than a fixed periodicity.

FIG. 6B illustrates a diagrammatical cross-section of a portion of an integrated circuit having contacts 651 of varying periodicity in accordance with an embodiment of the present invention. In FIG. 6B, the injector is represented by ESD diode 652, which will forward-bias and inject carriers into the p-substrate 650 when an overstress voltage is applied to I/O pad 653. The injector injects current into the integrated circuit at an injection site. Current at or near the injection site will have the highest density so contacts 651 near the ESD diode 652 will have the smallest periodicity, identified here as L1. Thus, periodicity L4 is greater than periodicity L3, which is greater than periodicity L2, which is greater than periodicity L1.

FIG. 6B illustrates well 655 having contacts 651 connected to pad 656. When well 655 is an n-well, contacts 651 comprise n+ regions coupled to Vdd through pad 656; when well 655 is a p-well, contacts 651 comprise p+ regions coupled to ground, or Vss, through pad 656. The regions 654 between contacts 651 include structures that may be susceptible to latch-up. Although an IC may utilize only n-well structures (or, alternatively, p-well structures), the majority of ICs will typically have both n-well and p-well structures within a given design.

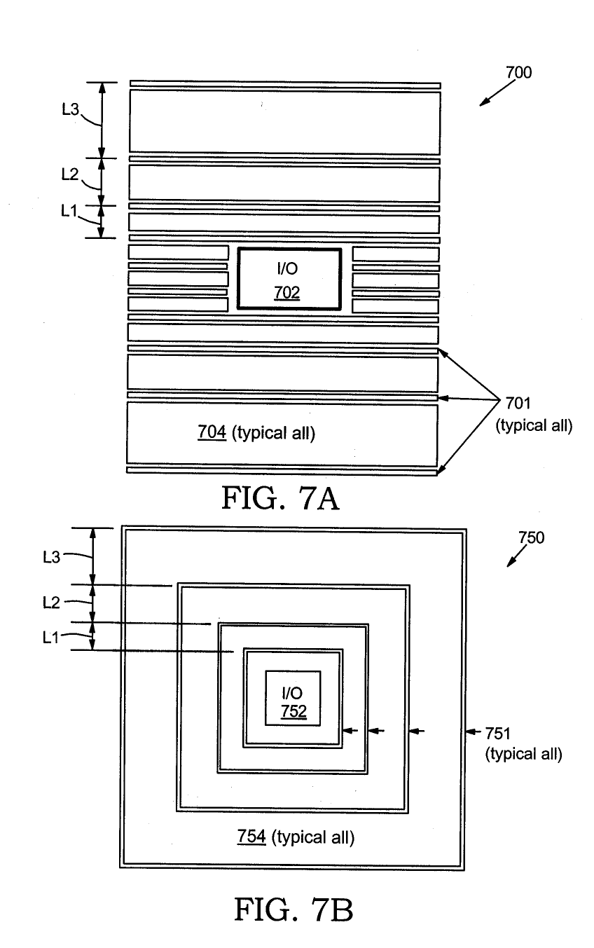

FIGS. 7A and 7B illustrate in plan view portions of integrated circuits having contacts of varying periodicity in accordance with alternate embodiments of this disclosure. FIG. 7A illustrates a portion of an integrated circuit 700 with contacts 701 arranged horizontally. In FIG. 7A, the injection site is I/O cell 702 so contact periodicity is smallest near this region. Thus, L3 is greater than L2, which is greater than L1. IC areas 704 include structures that may be susceptible to latch-up; for example, internal circuits that include n-wells and p-wells.

FIG. 7B illustrates a portion of an integrated circuit 750 with contacts 751 arranged concentrically. I/O cell 752 is the injector so nearby contacts 751 have a tighter periodicity. As distance is gained away from I/O cell 752, contact 751 periodicity increases. Thus, L3 is greater than L2, which is greater than L1. IC areas 754 include structures that may be susceptible to latch-up; for example, internal circuits that include n-wells and p-wells.

Integrated circuits described herein may be formed using any suitable material employed in fabricating semiconductor ICs. Such material includes, for example, silicon, germanium, silicon germanium, gallium arsenide, indium phosphide, as well as thick- and thin-film hybrid ICs, and n-wells and p-wells comprising circuit structures doped accordingly. Further, although integrated circuit embodiments disclosed herein have been described as having contacts arranged vertically, horizontally or concentrically, the invention is not limited to such configurations and is applicable to any contact arrangement. Numerous characteristics and advantages have been set forth in the foregoing description, together with details of structure and function. The novel features are pointed out in the appended claims. This disclosure, however, is illustrative only and changes may be made in detail within the principle of the invention to the full extent indicated by the broad general meaning of the terms in which the appended claims are expressed.

1. A semiconductor structure comprising:
a substrate;
a plurality of circuit structures formed upon said substrate, wherein at least one of said circuit structures has a susceptibility to a latch-up condition;
an injection site associated with said semiconductor structure; and
a plurality of contact regions inter-spaced a varying distance between said circuit structures.

2. The semiconductor structure of claim 1, wherein said distance varies with the proximity of said contact regions to said injection site.

3. The semiconductor structure of claim 1, wherein said distance varies with the susceptibility of said circuit structures to a latch-up condition.

4. The semiconductor structure of claim 1, wherein said plurality of contact regions comprises a first contact region and a second contact region spaced a first distance apart, and said second contact region and a third contact region spaced a second distance apart different from said first distance.

5. The semiconductor structure of claim 4, wherein said first distance is greater than said second distance.

6. The semiconductor structure of claim 4, wherein said first distance is less than said second distance.

7. The semiconductor structure of claim 1, wherein said substrate comprises a well region having formed therein said latch-up susceptible circuit structure.

8. The semiconductor structure of claim 7, wherein said well region is n-type.

9. The semiconductor structure of claim 8, wherein said n-type well region includes at least one contact comprising an n+ region.

10. The semiconductor structure of claim 9, wherein said at least one contact is coupled to Vdd.

11. The semiconductor structure of claim 7, wherein said well region is p-type.

12. The semiconductor structure of claim 11, wherein said p-type well region includes at least one contact comprising a p+ region.

13. The semiconductor structure of claim 12, wherein said at least one contact is coupled to ground.

14. The semiconductor structure of claim 12, wherein said at least one contact is coupled to Vss.

15. The semiconductor structure of claim 1, wherein said plurality of contact regions are located along an axis and arranged vertically relative to said axis.

16. The semiconductor structure of claim 1, wherein said plurality of contact regions are located along an axis and arranged horizontally relative to said axis.

17. The semiconductor structure of claim 1, wherein said plurality of contact regions are located along an axis and arranged concentrically relative to said axis.

18. The semiconductor structure of claim 1, wherein said distance is determined such that said latch-up susceptible circuit structure is prevented from latching-up when carriers are injected into the substrate from an external current injector.

19. The semiconductor structure of claim 18, wherein said external current injector is a cable discharge arising from a cable discharge event.

20. The semiconductor structure of claim 1, wherein said distance increases as the distance of said plurality of contact regions from said injection site increases.

21. The semiconductor structure of claim 1, wherein said plurality of contact regions are located along an axis so that spacing between adjacent contact regions increases as the distance from said injection site increases.

22. A method of forming a semiconductor structure having improved latch-up robustness, the method comprising the steps of:
providing a substrate including an injection site and a plurality of circuit structures, wherein at least one of said circuit structures has a susceptibility to a latch-up condition; and
forming a plurality of contact regions inter-spaced a varying distance between said circuit structures.

23. The method of claim 22, wherein said distance varies with the proximity of said plurality of contact regions to said injection site.

24. The method of claim 22, wherein said distance varies with the susceptibility of said circuit structures to a latch-up condition.

25. The method of claim 22, wherein said step of forming comprises forming a first contact region and a second contact region spaced a first distance apart, and said second contact region and a third contact region spaced a second distance apart different from said first distance.

26. The method of claim 25, wherein said first distance is greater than said second distance.

27. The method of claim 25, wherein said first distance is less than said second distance.

28. The method of claim 22, wherein said distance is determined such that said latch-up susceptible circuit structure is prevented from latching-up when carriers are injected into the substrate from an external current injector.

29. The method of claim 28, wherein said external current injector is a cable discharge arising from a cable discharge event.

30. The method of claim 22, wherein said distance increases as the distance of said plurality of contact regions from said injection site increases.

31. The method of claim 22, wherein said plurality of contact regions are located along an axis so that spacing between adjacent contact regions increases as the distance from said injection site increases.

32. A program storage device readable by a machine, tangibly embodying a program of instructions executable by a machine to perform a method of designing an integrated circuit, the method comprising the steps of:
receiving an integrated circuit design, said design providing for a plurality of circuit structures within a substrate;
identifying at least one injection site associated with said integrated circuit design;
identifying circuit structures as susceptible to a latch-up condition;
determining a plurality of contacts for said circuit structures susceptible to a latch-up condition, said quantity being that necessary to suppress a latch-up condition within said identified circuit structures; and
determining a location for said contacts so that said contacts are located to have a distance that varies with the proximity of said contacts to said at least one injection site.

33. The method of claim 32, wherein said substrate comprises a well region having formed therein at least one of said latch-up susceptible circuit structures.

34. The method of claim 32 further comprising the step of determining an aggregate contact layout.

35. The method of claim 32, wherein the step of determining said distance comprises limiting said quantify of contacts to a minimum number that suppresses a latch-up condition within said latch-up susceptible circuit structures.

36. The method of claim 32, wherein the step of determining said distance comprises identifying an aggregate contact layout responsive to said distance determination.

37. The method of claim 32, wherein the step of identifying said at least one injection site comprises identifying a location and an injection current magnitude for said at least one injection site.

38. The method of claim 32, wherein the step of identifying circuit structures as susceptible to a latch-up condition comprises identifying a location and physical attributes for each of said circuit structures susceptible to a latch-up condition.

39. The method of claim 38, wherein one of said physical attributes is resistance.

40. A computer-readable medium having a plurality of computer executable instructions for causing a computer to design an integrated circuit, the computer executable instructions comprising the steps of:
receiving an integrated circuit design, said design providing for a plurality of circuit structures within a substrate;
identifying at least one injection site associated with said integrated circuit design;
identifying circuit structures as susceptible to a latch-up condition;
determining a quantity of contacts for said circuit structures susceptible to a latch-up condition, said quantity being that necessary to suppress a latch-up condition within said identified circuit structures; and
determining a varying distance for said contacts, wherein said distance varies with the proximity of said contacts to said at least one injection site.

41. The computer-readable medium of claim 40, wherein said medium comprises hardware.

42. The computer-readable medium of claim 40, wherein said medium comprises firmware.

43. The computer-readable medium of claim 40, wherein said computer-readable medium is configured to maintain one or more data structures and store data, wherein said instructions are executed seriatim as part of a loop structure wherein retrieved data is stored within said one or more data structures.

44. The computer-readable medium of claim 43, wherein said data originates externally from the medium.

45. The computer-readable medium of claim 40, wherein said instructions are executed to retrieve data from one or more data structures, said data representing variables associated with said substrate, circuit structures, wells, contacts, and periodicity.

46. The computer-readable medium of claim 40, wherein said design is software implemented and comprises software components that represent constituent elements of the design.

47. The computer-readable medium of claim 46, wherein said constituent elements include substrate, circuit structures, and wells.

48. The computer-readable medium of claim 46, wherein said software components comprise data structures.

49. The computer-readable medium of claim 48, wherein said data structures are embedded within said software implemented design.

50. The computer-readable medium of claim 46, wherein said software components maintain data and wherein said instructions are executed to retrieve data from said software components, said data representing variables associated with said substrate, circuit structures, wells, contacts, and periodicity.

51. The computer-readable medium of claim 48, wherein said design is implemented in an object oriented platform and said data structures are objects.
